(19) United States
(12) Patent Application Publication
(10) Pub. No.: US 2025/0267943 A1
(43) Pub. Date: Aug. 21, 2025

(54) Thin-Film Transistor Substrate and Display Device Including the Same

(71) Applicant: LG Display Co., Ltd., Seoul (KR)

(72) Inventors: Dohun Kwak, Paju-si (KR); Deukho Yeon, Paju-si (KR); Daehwan Kim, Goyang-si (KR)

(21) Appl. No.: 19/001,980

(22) Filed: Dec. 26, 2024

(30) Foreign Application Priority Data
Feb. 20, 2024 (KR) 10-2024-0024090

(51) Int. Cl. H10D 86/40; H10D 86/60

(52) U.S. Cl. CPC H10D 86/471; H10D 86/423; H10D 86/481; H10D 86/60

(57) ABSTRACT

Disclosed is a thin-film transistor substrate in which carrier mobilities of active layers of a first thin-film transistor and a second thin-film transistor which require different characteristics are set to be different from each other, thereby satisfying both the different characteristics required for the first and second thin-film transistors having different functions. Further, a display device including the thin-film transistor substrate is disclosed.

### CROSS-REFERENCE TO RELATED APPLICATION

This application claims priority from Republic of Korea Patent Application No. 10-2024-0024090 filed on Feb. 20, 2024, which is hereby incorporated by reference in its entirety.

### BACKGROUND

### Field

The present disclosure relates to a thin-film transistor substrate and a display device including the thin-film transistor substrate.

### Description of Related Art

A display device is used in a variety of devices such as televisions, monitors, smart phones, tablet personal computers (PCs), laptops, and wearable devices.

The display device may display an image through a number of pixels included in a display area.

In this case, each pixel may include at least one thin-film transistor that may individually control each pixel.

Recently, consumer demand for an ultra-high resolution display device is increasing, and thus, the display area is required to include a larger number of pixels.

When an area size occupied by each pixel included in the display area is reduced, a size of an element such as the thin-film transistor included in the pixel may be reduced.

### SUMMARY

The display device may include not only thin-film transistor elements included in a pixel disposed in a display area, but also thin-film transistor elements included in a gate driver disposed in a non-display area.

These thin-film transistors may be classified into thin-film transistors with various functions such as switching transistors, driving transistors, and sensing transistors.

The thin-film transistors with these various functions may have different required characteristics.

For example, the switching transistor may require highly reliable switching characteristics, while the driving transistor may require high current characteristics.

These thin-film transistors may be implemented in various types, such as Low Temperature Poly Silicon (LTPS) thin-film transistors, oxide thin-film transistors, and Low Temperature Polycrystalline Oxide (LTPO) thin-film transistors, depending on a material of an active layer and a process for forming the active layer,

In one example, the thin-film transistor is embodied as an oxide thin-film transistor. In this case, when forming the active layer with a material with relatively low carrier mobility to increase the reliability of the switching characteristics of the switching transistor, the switching characteristics of the switching transistor may be improved. However, it may be difficult to achieve the high current characteristics of the driving transistor.

On the contrary, in order to achieve the high current characteristics of the driving transistor, the active layer may be made of a material with relatively high carrier mobility. In this case, although the high current characteristics of the driving transistor may be improved, the reliability of the switching characteristics of the switching transistor deteriorates.

Accordingly, there is a need to implement technology that may satisfy all the characteristics required for the thin-film transistors with the different functions.

As user demand for a display device with a narrow bezel increases, technology to reduce an area occupied with the non-display area is required.

The gate driver may be placed in the non-display area, and a width of the bezel may be reduced by reducing an area occupied with the gate driver.

For example, the area occupied with the gate driver may be reduced by reducing a size of the thin-film transistor included in the gate driver.

The size of the thin-film transistor may be reduced by reducing a size of the active layer. However, when the size of the active layer is reduced, the characteristics of the thin-film transistor that requires the high current characteristics such as the driving transistor may deteriorate.

Accordingly, it is necessary to secure technology that may prevent the characteristics of the thin-film transistor which requires high current characteristics from deteriorating even when the size of the thin-film transistor is reduced to implement a narrow bezel.

In one of schemes for applying high current to the thin-film transistor, an active layer of the thin-film transistor may be made of a high-carrier mobility oxide semiconductor material.

However, when the active layer is made of the high-carrier mobility oxide semiconductor material, hot carrier stress (HCS) may occur in a channel area adjacent to a drain electrode of the thin-film transistor.

The hot carrier stress may be described as follows.

When the drain voltage applied to the thin-film transistor increases beyond a certain value, electrons migrating through the channel area have strong migration energy, thereby causing strong collisions of the electrons in the channel area near the drain area.

Due to such strong collisions of the electrons, defects may occur in the channel area near the drain area, or a hot carrier stress phenomenon in which the electrons are trapped may occur.

When the hot carrier stress phenomenon occurs, current characteristics of the thin-film transistor element decreases, which may lead to a defect in which a certain pixel in the display panel does not properly operates.

In particular, when the active layer is made of the high-carrier mobility oxide semiconductor material, a possibility at which the hot carrier stress occurs may increase due to a high carrier concentration.

In this way, when the active layer of the thin-film transistor is made of a high-carrier mobility oxide semiconductor material, the high current may be imparted to the thin-film transistor, while the occurrence of the hot carrier stress phenomenon may lead to reduced current characteristics of the transistor or the defect of the transistor.

Accordingly, through various experiments, the inventors of the present disclosure have invented a thin-film transistor substrate that may implement a narrow bezel while satisfying all of the different characteristics required for different thin-film transistors, and a display device including the same.

A purpose according to an embodiment of the present disclosure is to provide a thin-film transistor substrate that may satisfy all the different characteristics required for a plurality of thin-film transistors with different functions and a display device including the same.

In addition, a purpose according to an embodiment of the present disclosure is to provide a thin-film transistor substrate that may implement both thin-film transistors respectively requiring high current characteristics and high switching characteristics and a display device including the same.

Additionally, a purpose according to an embodiment of the present disclosure is to provide a thin-film transistor substrate with a narrow bezel and a display device including the same.

Furthermore, a purpose according to an embodiment of the present disclosure is to provide a thin-film transistor substrate that may reduce the occurrence of the hot carrier stress phenomenon and a display device including the same.

In addition, a purpose according to an embodiment of the present disclosure is to provide a thin-film transistor substrate capable of achieving high luminance and a display device including the same.

In addition, a purpose according to an embodiment of the present disclosure is to provide a thin-film transistor substrate that may facilitate control of a threshold voltage and a display device including the same.

In addition, a purpose according to an embodiment of the present disclosure is to provide a thin-film transistor substrate that may increase productivity and reliability of the active layer and achieve production energy saving via process optimization, and a display device including the same.

In addition, a purpose according to an embodiment of the present disclosure is to provide a thin-film transistor substrate that is advantageous in terms of grayscale expression and a display device including the same.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

In one embodiment, a thin-film transistor substrate comprises: a substrate including a display area and a non-display area; a first thin-film transistor on the non-display area of the substrate, the first thin-film transistor including a first active layer having a first side portion and a second side portion that is opposite the first side portion and has a second carrier mobility that is different from a first carrier mobility of the first side portion; and a second thin-film transistor on the display area of the substrate, the second thin-film transistor including a second active layer having a carrier mobility that is less than the first carrier mobility of the first side portion and the second carrier mobility of the second side portion of the first active layer.

In one embodiment, a display device comprises: a substrate including a display area and a non-display area; a light-emitting element on the display area of the substrate, the light-emitting element configured to emit light; and a gate driver on the non-display area of the substrate and configured to provide a gate voltage to the display area, the gate driver including a first thin-film transistor on the non-display area that comprises a first active layer, a first drain electrode, a first source electrode, and a first gate electrode, wherein the first active layer includes a first drain active layer connected to the first drain electrode and having a first carrier mobility and a first source active layer connected to the first source electrode and including a second carrier mobility that is greater than the first carrier mobility of the first drain electrode.

In one embodiment, a thin-film transistor comprises: an oxide semiconductor layer comprising a drain active layer having a first carrier mobility and a source active layer having a second carrier mobility that is greater than the first carrier mobility; a gate electrode overlapping a portion of oxide semiconductor layer and is spaced apart from the portion of the oxide semiconductor layer; a drain electrode that is connected to the drain active layer; and a source electrode that is connected to the source active layer.

According to an embodiment of the present disclosure, the carrier mobilities of the active layers of the first thin-film transistor and the second thin-film transistor which require different characteristics are set to be different from each other, thereby satisfying both the different characteristics required for the first and second thin-film transistors having the different functions.

Further, according to an embodiment of the present disclosure, in the first thin-film transistor requiring high current characteristics, the active layer may be configured to have relatively high carrier mobility, while in the second thin-film transistor requiring high switching characteristics, the active layer may be configured to have a relatively low carrier mobility. Thus, both the thin-film transistors respectively requiring high current characteristics or high switching characteristics may be realized.

Furthermore, according to an embodiment of the present disclosure, the active layer of the thin-film transistor included in the gate driver has the relatively high carrier mobility. Thus, even when a length of the active layer is reduced, the high current characteristics may be secured.

Accordingly, the size of the thin-film transistor may be reduced such that the area occupied with the gate driver may be reduced, making it possible to implement a display device with a narrow bezel.

Moreover, according to an embodiment of the present disclosure, in the first thin-film transistor, the carrier mobility of the first drain active layer connected to the first drain electrode is lower than that of the first source active layer connected to the first source electrode. Thus, even when the first source active layer is made of a high-carrier mobility material, the occurrence of the hot carrier stress in the first drain active layer may be reduced.

Further, according to an embodiment of the present disclosure, a significant area of an effective channel area of the first active layer of the first thin-film transistor constituting the main channel may be made of a relatively high carrier mobility material. Thus, high current may be allowed to flow through the thin-film transistor, such that a display device with high luminance may be realized.

Further, according to an embodiment of the present disclosure, as the active layer is formed as a stack of a plurality of layers with different carrier mobility, it is easier to control a threshold voltage in the active layer based on high current characteristics.

In addition, according to an embodiment of the present disclosure, as the first active layer of the first thin-film transistor is formed as a stack of a plurality of layers with different carrier mobility, a limited range on process conditions as required in a process of forming the active layer may be expanded, compared to forming the active layer as a single layer.

Accordingly, not only may the productivity and reliability of the active layer be improved, but production energy savings may be achieved through process optimization.

Further, according to an embodiment of the present disclosure, the S-factor value may be increased by electrically connecting the first light blocking layer disposed under the first thin-film transistor to the first source electrode thereof. Thus, the display device may express sufficient gradations. This may be advantageous in terms of the gradation expression.

Effects of the present disclosure are not limited to the effects mentioned above, and other effects not mentioned will be clearly understood by those skilled in the art from the descriptions below.

### BRIEF DESCRIPTION OF DRAWINGS

FIG. 1 is a schematic plan view of a display device according to an embodiment of the present disclosure.

FIG. 2 is a circuit diagram of one sub-pixel of a display device according to an embodiment of the present disclosure.

FIG. 3 is a schematic circuit diagram of a gate driver according to an embodiment of the present disclosure.

FIGS. 4 to 10 are cross-sectional views of a thin-film transistor substrate including a first thin-film transistor and a second thin-film transistor according to first to seventh embodiments of the present disclosure, respectively.

FIG. 11 is a cross-sectional view of a thin-film transistor substrate including a first thin-film transistor and a third thin-film transistor according to an embodiment of the present disclosure.

FIG. 12 is a plan view including a first thin-film transistor according to an embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be embodied in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

A shape, a size, a ratio, an angle, a number, etc. disclosed in the drawings for illustrating embodiments of the present disclosure are illustrative, and the present disclosure is not limited thereto. For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof.

In interpreting a numerical value, the value is interpreted as including an error range unless there is no separate explicit description thereof.

Further, as used herein, when a layer, film, region, plate area, or the like is be disposed “on” or “on a top” of another layer, film, region, plate area, or the like, the former may directly contact the latter or still another layer, film, region, plate area, or the like may be disposed between the former and the latter. As used herein, when a layer, film, region, plate area, or the like is directly disposed “on” or “on a top” of another layer, film, region, plate area, or the like, the former directly contacts the latter and still another layer, film, region, plate area, or the like is not disposed between the former and the latter. Further, as used herein, when a layer, film, region, plate area, or the like is disposed “below” or “under” another layer, film, region, plate area, or the like, the former may directly contact the latter or still another layer, film, region, plate area, or the like may be disposed between the former and the latter. As used herein, when a layer, film, region, plate area, or the like is directly disposed “below” or “under” another layer, film, region, plate area, or the like, the former directly contacts the latter and still another layer, film, region, plate area, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be embodied independently of each other and may be embodied together in an association relationship.

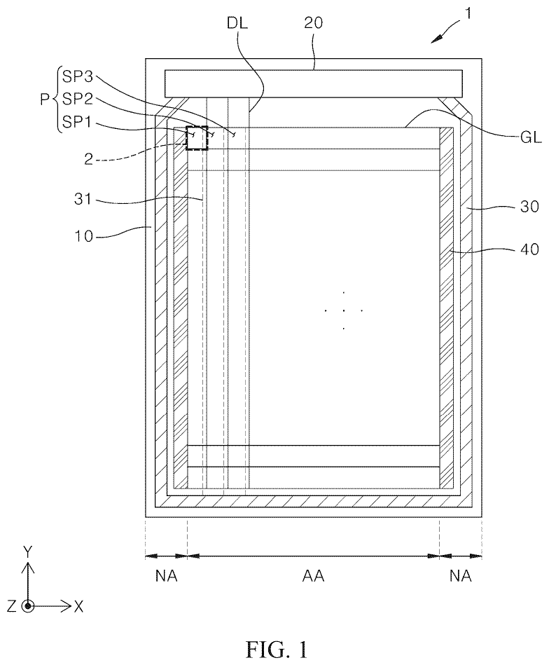

Hereinafter, with reference to FIG. 1 to FIG. 3, a display device according to an embodiment of the present disclosure will be described in detail.

FIG. 1 is a schematic plan view of a display device according to an embodiment of the present disclosure.

An example in which a display device 1 is embodied as an organic electroluminescent display device (organic light-emitting diode display device) is described below. However, embodiments of the present disclosure are not limited thereto.

The display device 1 may include a substrate 10 including a display area AA and a non-display area NA surrounding the display area AA.

In the display area AA of the substrate 10, a plurality of data lines DL extending in a first direction and a plurality of gate lines GL extending in a second direction intersecting the first direction may be arranged.

Each of sub-pixels SP1, SP2, and SP3 may be disposed in each of intersections of the data lines DL and the gate lines GL.

The sub-pixels SP1, SP2, and SP3 may emit light of the same color, such as white (W) light, or red (R), green (G), or blue (B) light, or may emit light beams of different colors.

A combination of the plurality of sub-pixels SP1, SP2, and SP3 as described above may constitute one pixel P.

The plurality of sub-pixels SP1, SP2, and SP3 may be arranged in a plurality of rows and columns in a matrix format.

As used herein, the first direction may be a column direction and may be defined as a Y-axis direction, and the second direction may be a row direction and may be defined as a X-axis direction.

A number of lines and pads that supply various signals and powers to the pixel may be disposed on the non-display area NA of the substrate 10.

A data driver circuit (D-IC) 20 may be disposed in one side area of the non-display area NA.

The data driver circuit 20 may apply a data signal to the data line DL, and may apply a driving voltage such as a high potential voltage VDD or a low potential voltage VSS to the pixel P.

A power line 30 may extend along an edge of the display area AA and in a side area of the non-display area NA other than the side area in which the data driver circuit 20 is disposed.

For example, a gate driver 40 that applies a gate signal to the gate line GL may be disposed in the non-display area NA and disposed on each of both opposing sides of the display area AA. The power line 30 capable of applying a voltage to an anode electrode or a cathode electrode in the pixel P may extend along an outer edge of the gate driver 40 and in the non-display area NA.

The gate driver 40 formed on the substrate 10 with a gate-in-panel (GIP) scheme may be named a GIP driver.

The power line 30 may include a low-potential voltage line capable of applying a low-potential voltage VSS to the cathode electrode of the pixel P. However, embodiments of the present disclosure are not limited thereto. The power line 30 may further include a high-potential voltage line capable of applying a high-potential voltage VDD to a thin-film transistor of the pixel P.

A plurality of power connection lines 31 may be disposed in the display area AA and may be electrically connected to and disposed between the power line 30 and the plurality of sub-pixels SP1, SP2, and SP3 and may apply the low potential voltage to the plurality of sub-pixels SP1, SP2, and SP3.

For example, the plurality of power connection lines 31 may extend in the first direction in which the plurality of data lines DL extend by an equal length.

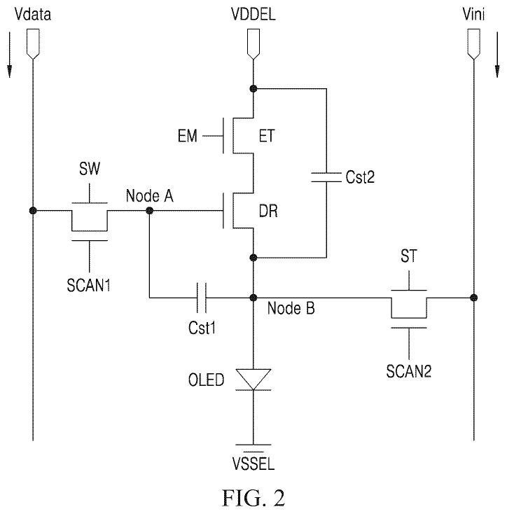

FIG. 2 is a circuit diagram of one sub-pixel of a display device according to an embodiment of the present disclosure.

An example in which the sub-pixel is implemented based on a 4T (Transistor) 2C (Capacitor) structure is described. However, embodiments of the present disclosure are not limited thereto.

For example, the sub-pixel includes a first storage capacitor Cst1, a second storage capacitor Cst2, a switching transistor SW, a light-emission control transistor ET, a sensing transistor ST, a driving transistor DR, and light-emitting element OLED.

Each of the switching transistor SW, the light-emission control transistor ET, and the sensing transistor ST may act as a switch.

A first scan signal SCAN1, a second scan signal SCAN2, and a third scan signal EM may be provided to the sub-pixel via the gate line GL, and a data voltage Vdata may be provided to the sub-pixel via the data line DL.

The switching transistor SW may be used to apply the voltage of the data line DL to a node A.

The switching transistor SW may be turned on or turned off based on the first scan signal SCAN1.

The node A may be connected to a gate electrode of the driving transistor DR.

The sensing transistor ST may be used to apply an initialization voltage Vini to a node B to initialize a circuit while a compensation operation is performed.

The sensing transistor ST may be turned on or turned off based on the second scan signal SCAN2.

The light-emission control transistor ET may be turned on or off based on the third scan signal EM (e.g., an emission signal).

The switching transistor SW may perform a switching operation to store the data voltage Vdata in the first capacitor Cst1 in response to the first scan signal SCAN1.

The driving transistor DR may operate so that a driving current flows between a high-potential power line VDDEL and a low-potential power line VSSEL based on the data voltage stored in the first capacitor Cst1.

The driving transistor DR may be turned on based on the data voltage to control current flowing through the light-emitting element OLED to display an image.

The light-emitting element OLED may emit light based on a current of a high potential voltage transmitted via the driving transistor DR.

One side of the light-emitting element OLED may be connected to the node B, and the other side thereof may be connected to the low-potential power line VSSEL.

In the present disclosure, the light-emitting element OLED may be embodied as an organic light-emitting diode. However, embodiments of the present disclosure are not limited thereto. Various types of light-emitting elements may be used as the light-emitting element.

The second capacitor Cst2 may be a compensation capacitor and, for example, may compensate for a threshold voltage of the driving transistor DR.

One side of the second capacitor Cst2 may be connected to one side of the driving transistor DR, and the other side thereof may be connected to the other side of the light-emission control transistor ET.

Each of the switching transistor SW and the sensing transistor ST may have a double gate structure in which gate electrodes are disposed on top of and under one active layer, respectively.

As each of the switching transistor SW and the sensing transistor ST has the double gate structure, switching performance may be improved by improving on-off characteristics of the transistor.

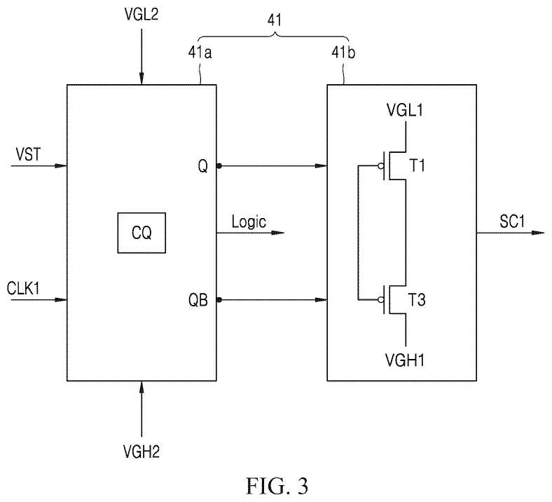

FIG. 3 is a schematic circuit diagram of a gate driver according to an embodiment of the present disclosure.

A gate driving circuit 41 according to an embodiment of the present disclosure may include a logic signal generator 41a, and a first scan signal generator 41b that shares a Q node and a QB node of the logic signal generator 41a and is configured to generate a first scan signal SC1.

The logic signal generator 41a may receive a start pulse VST, a second high potential voltage VGH2, a second low potential voltage VGL2, and a first clock CLK1 and output a carry signal Logic.

The first scan signal generator 41b may share the Q node and the QB node of the logic signal generator 41a, may receive a first high potential voltage VGH1 and a first low potential voltage VGL1 and may output the first scan signal SC1.

One or more thin-film transistors may be included in the first scan signal generator 41b. For example, a first thin-film transistor T1 and a third thin-film transistor T3 may be disposed in the first scan signal generator 41b.

The first thin-film transistor T1 may receive the first low-potential voltage VGL1 from one side, and the third thin-film transistor T3 may receive the first high-potential voltage VGH1 from one side. The first thin-film transistor T1 and the third thin-film transistor T3 may be connected to each other.

The first thin-film transistor T1 and the third thin-film transistor T3 will be described in detail later.

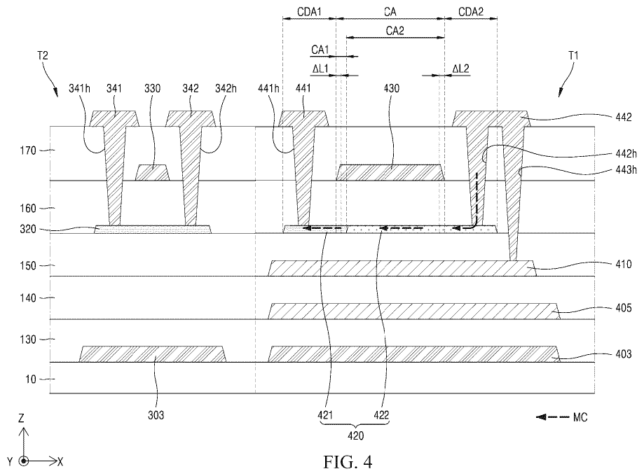

Hereinafter, with reference to FIG. 4, the first thin-film transistor T1 and a second thin-film transistor T2 according to a first embodiment of the present disclosure will be described in detail.

The first thin-film transistor T1 may be embodied as a GIP type driving thin-film transistor disposed in the gate driver 40 in the non-display area NA.

The second thin-film transistor T2 may be embodied as a switching thin-film transistor disposed in the pixel P in the display area AA.

Referring to FIG. 4, a substrate 10 may be disposed, and the substrate 10 may be referred to as a thin-film transistor substrate.

Glass or plastic such as polyimide may be used as a material of the substrate 10.

A first light blocking layer 410 may be disposed on the substrate 10.

A first capacitor electrode 403 may be disposed on the substrate 10 in an area where the first thin-film transistor T1 is disposed (e.g., overlapping the first thin-film transistor T1), while a second lower gate electrode 303 may be disposed on the substrate 10 in an area where the second thin-film transistor T2 is disposed (e.g., overlapping the second thin-film transistor T2). The first capacitor electrode 403 and the second lower gate electrode 303 may be disposed in the same layer.

A first interlayer insulating layer 130 may be disposed on the first capacitor electrode 403 and the second lower gate electrode 303.

A second capacitor electrode 405 may be formed on the first interlayer insulating layer 130 in an area where the first thin-film transistor T1 is disposed (e.g., overlapping the first thin-film transistor T1).

The first capacitor electrode 403 and the second capacitor electrode 405 may constitute a capacitor CQ included in the gate driver 40 and, for example, may be disposed in the logic signal generator 41a.

A second interlayer insulating layer 140 may be disposed on the second capacitor electrode 405.

Each of the first interlayer insulating layer 130 and the second interlayer insulating layer 140 may be composed of a single layer or a stack of multiple layers made of silicon oxide (SiOx) or silicon nitride (SiNx). However, embodiments of the present disclosure are not limited thereto.

The first light blocking layer 410 may be disposed on the second interlayer insulating layer 140 in the area where the first thin-film transistor T1 is disposed.

The first light blocking layer 410 may protect a first active layer 420 of the first thin-film transistor T1 by blocking light incident from the outside of the display device.

Accordingly, the first light blocking layer 410 may be positioned to overlap the first active layer 420 in a vertical direction. As shown in FIG. 4, the first light blocking layer 410 is between the substrate 10 and the first thin-film transistor T1.

The vertical direction in FIG. 4 may mean a Z-axis direction.

The first light blocking layer 410 may be formed to have a larger area than that of the first active layer 420, and thus may effectively block light incident from a position under the first active layer 420.

A buffer layer 150 may be disposed on the first light blocking layer 410.

The buffer layer 150 may be composed of a single or double layer made of silicon oxide (SiOx) or silicon nitride (SiNx). However, embodiments of the present disclosure are not limited thereto.

The buffer layer 150 may protect the first active layer 420 by blocking air and moisture.

The first active layer 420 may be disposed on the buffer layer 150.

The first active layer 420 may include a first drain active layer 421 and a first source active layer 422 having different carrier mobility. That is, the first drain active layer 421 has a first carrier mobility and the first source active layer 422 has a second carrier mobility that is different from the first carrier mobility.

The first drain active layer 421 and the first source active layer 422 may be arranged side by side and may be disposed in the same plane.

For example, the first drain active layer 421 and the first source active layer 422 may be arranged side by side and may be disposed on the buffer layer 150.

Each of the first drain active layer 421 and the first source active layer 422 may be formed as a single layer.

A length in a left-right direction of the first source active layer 422 may be larger than a length in the left-right direction of the first drain active layer 421. That is, the length of the first source active layer 422 is longer than a length of the first drain active layer 421 in the cross-section view of the display device.

The left-right direction as indicated in FIG. 4 may refer to the X-axis direction.

Each of the first drain active layer 421 and the first source active layer 422 may include an oxide semiconductor material.

The first drain active layer 421 may have lower carrier mobility than that of the first source active layer 422. Thus, the first carrier mobility of the first carrier mobility that is less than the second carrier mobility of the first source active layer 422 due to the shorter length of the first drain active layer 421.

Accordingly, the first drain active layer 421 may be made of an oxide semiconductor material with low carrier mobility characteristics, and the first source active layer 422 may be made of an oxide semiconductor material with high carrier mobility characteristics with respect to the first drain active layer 421.

As used herein, the low carrier mobility and the high carrier mobility are relative concepts. Mobility values of the first drain active layer 421 and the first source active layer 422 are compared to each other, and a relatively lower carrier mobility value may be referred to as the low carrier mobility, and a relatively higher carrier mobility value may be referred as the high carrier mobility.

In one example, the first drain active layer 421 of the low carrier mobility may include at least one of an IGZO (InGaZnO)-based oxide semiconductor material [Ga concentration≥In concentration], a GZO (GaZnO)-based oxide semiconductor material, an IGO (InGaO)-based oxide semiconductor material, and a GZTO (GaZnSnO)-based oxide semiconductor material.

For example, the first drain active layer 421 may have a carrier mobility in a range from approximately 5 cm²/V·s to 12 cm²/V·s. However, embodiments of the present disclosure are not limited thereto.

In one example, the first source active layer 422 of the high carrier mobility may include at least one of an IGZO (InGaZnO)-based oxide semiconductor material [In concentration>Ga concentration], an IZO (InZnO)-based oxide semiconductor material, an IGZTO (InGaZnSnO)-based oxide semiconductor material, a ITZO (InSnZnO)-based oxide semiconductor material, a FIZO (FeInZnO)-based oxide semiconductor material, a ZnO-based oxide semiconductor material, a SIZO (SiInZnO)-based oxide semiconductor material, and a ZnON (Zn-Oxynitride)-based oxide semiconductor material.

For example, the first source active layer 422 may have a carrier mobility ranging from approximately 20 cm²/V·s to 50 cm²/V·s. However, embodiments of the present disclosure are not limited thereto. Thus, the carrier mobility of the first source active layer 422 is roughly four times greater than the carrier mobility of the first drain active layer 421.

A gate insulating layer 160 may be disposed on the first active layer 420.

The gate insulating layer 160 may be composed of a single or double layer of silicon oxide (SiOx) or silicon nitride (SiNx). However, embodiments of the present disclosure are not limited thereto.

A first gate electrode 430 may be disposed on the gate insulating layer 160 and is spaced apart from the first active layer 420.

The first gate electrode 430 may be disposed to overlap the first active layer 420 in the vertical direction.

The first gate electrode 430 may be formed to have a smaller area than that of the first active layer 420.

A third interlayer insulating layer 170 may be disposed on the first gate electrode 430.

The third interlayer insulating layer 170 may be composed of a single or double layer of silicon oxide (SiOx) or silicon nitride (SiNx). However, embodiments of the present disclosure are not limited thereto.

A first drain electrode 441 and a first source electrode 442 may be disposed on the third interlayer insulating layer 170.

The first drain electrode 441 may be connected to the first drain active layer 421 as one portion of the first active layer 420 via a first contact hole 441h extending through the third interlayer insulating layer 170 and the gate insulating layer 160.

One area of the first active layer 420 where the first drain active layer 421 is located may be defined as a first area.

In addition, the first source electrode 442 may be connected to the first source active layer 422 as the other portion of the first active layer 420 via a second contact hole 442h extending through the third interlayer insulating layer 170 and the gate insulating layer 160.

The other area of the first active layer 420 where the first source active layer 422 is located may be defined as a second area.

In addition, the first source electrode 442 may be connected to the first light blocking layer 410 via a third contact hole 443h extending through the third interlayer insulating layer 170, the gate insulating layer 160, and the buffer layer 150.

Accordingly, the first active layer 420 and the first light blocking layer 410 may be electrically connected to each other via the first source electrode 442.

According to an embodiment of the present disclosure, electrically connecting the first source electrode 442 and the first light blocking layer 410 disposed under the first thin-film transistor T1 to each other may allow a S-factor value to be increased. Thus, the display device may express sufficient gradations, which may be advantageous in terms of gradation expression.

The S-factor is referred to as “subthreshold slope” and indicates a voltage required when the current increases by 10 times. In a graph (I-V curve) showing characteristics of a drain current relative to a gate voltage, the S-factor value is a reciprocal value of a slope of the graph (I-V curve) in a range below the threshold voltage.

A small S-factor value means that the slope of the characteristic graph I-V of the drain current relative to the gate voltage is large.

Therefore, the thin-film transistor may be turned on even under a small voltage, and the switching characteristics of the thin-film transistor may be improved.

On the other hand, since the voltage reaches the threshold voltage in a short time, it may be difficult to express sufficient grayscale.

Conversely, a large S-factor value means that the slope of the characteristic graph I-V of the drain current relative to the gate voltage is small.

Therefore, the switching characteristics of the thin-film transistor may deteriorate due to decrease in an on/off response speed of the thin-film transistor, while sufficient grayscale expression may be achieved because the voltage reaches the threshold voltage over a relatively long period of time.

When the first light blocking layer 410 disposed under the first active layer 420 is not connected to the first source electrode 442, the first light blocking layer 410 plays the same role as that of the gate electrode, such that the switching characteristics of the transistor may be improved.

However, as described above, when the switching characteristics are improved, the voltage reaches the threshold voltage in a short time, thus making it difficult to express sufficient grayscale. Therefore, the first light blocking layer 410 according to an embodiment of the present disclosure may be electrically connected to the first source electrode 442, such that the thin-film transistor may provide for sufficient grayscale expression.

In another embodiment, the first light blocking layer 410 may not be in contact with the first source electrode 442, but may be connected to another electrode or line so as to be connected to a ground electrode.

The first thin-film transistor T1 may include the first active layer 420, the first gate electrode 430, the first drain electrode 441, and the first source electrode 442 formed in this way.

The first thin-film transistor T1 according to an embodiment of the present disclosure is constructed so that the first drain electrode 441 and the first source electrode 442 have an asymmetric structure with each other, and may be configured as a unidirectional element in which current flows only in a direction from the first source electrode 442 to the first drain electrode 441.

An area of the first active layer 420 that overlaps the first gate electrode 430 in the vertical direction may be a channel area CA.

Accordingly, an area of each of the first drain active layer 421 and the first source active layer 422 constituting the first active layer 420 overlapping the first gate electrode 430 in the vertical direction may be the channel area CA.

An area where the first drain active layer 421 and the first gate electrode 430 overlap each other in the vertical direction may be a first channel area CA1. An area where the first source active layer 422 and the first gate electrode 430 overlap each other in the vertical direction may be the second channel area CA2.

An area of the first active layer 420 that does not overlap the first gate electrode 430 in the vertical direction may be a conductivized area CDA1 and CDA2. A conductivized area may refer, for example, to an area that has been made conductive by a treatment to be described in the following performed after deposition of the respective material which becomes conductive upon being treated, i.e., conductivized areas CDA1 and CDA2 are areas CDA1 and CDA2 that have been made conductive after deposition of the material forming the first active layer 420.

For example, the channel area CA and the conductivized area CDA1 and CDA2 may be formed in the first active layer 420 by plasma treatment or hydrogen treatment using the first gate electrode 430 as a mask.

The first drain active layer 421 connected to the first drain electrode 441 may act as the first conductivized area CDA1 in an area thereof that does not overlap with the first gate electrode 430. The first drain active layer 421 connected to the first drain electrode 441 may act as the first channel area CA1 in an area thereof that overlaps with the first gate electrode 430.

The first drain active layer 421 may be positioned so that a partial area thereof overlaps the first gate electrode 430 in the vertical direction so as to act as the first channel area CA1.

The first source active layer 422 connected to the first source electrode 442 may act as the second conductivized area CDA2 in an area thereof that does not overlap with (e.g., non-overlapping) the first gate electrode 430. The first source active layer 422 connected to the first source electrode 442 may act as the second channel area CA2 in an area thereof that overlaps with the first gate electrode 430.

The first source active layer 422 may be positioned such that a partial area thereof overlaps the first gate electrode 430 in the vertical direction so as to act as the second channel area CA2.

In this case, the first source active layer 422 may be formed to have a larger overlapping area with the first gate electrode 430 than an area of the first drain active layer 421 overlapping with the first gate electrode 430.

Accordingly, a length of the second channel area CA2 of the high carrier mobility may be larger than the length of the first channel area CA1 of the low carrier mobility.

A main portion of the channel area CA through which a larger number of carriers migrate may be referred to as a main channel area.

However, depending on a stacking type of the first active layer 420, the channel area may include a sub-channel area in addition to the main channel area.

The carriers may migrate in the sub-channel area. However, a smaller number of carriers may migrate, compared to the main channel area.

When the first active layer 420 is formed as a single layer, both the second channel area CA2 and the first channel area CA1 arranged side by side and disposed in the same plane may be the main channel areas.

The first channel area CA1 and the second channel area CA2 may be arranged so as not to overlap each other (e.g., non-overlapping) in the vertical direction.

Accordingly, main current MC may flow from the first source electrode 442 to the first drain electrode 441 via the second channel area CA2 and the first channel area CA1.

In this case, since the length of the second channel area CA2 of the high carrier mobility is larger than the length of the first channel area CA1 of the low carrier mobility, the second channel area CA2 of the high carrier mobility may occupy a significant portion of the main channel area.

According to an embodiment of the present disclosure, the significant portion of the main channel area in the channel area CA of the first active layer 420 may be made of a relatively high carrier mobility material, so that high current may be allowed to flow through the thin-film transistor. Thus, a display device with high luminance may be realized.

A first boundary area ΔL1 and a second boundary area ΔL2 may be disposed at one side of the channel area CA adjacent to the first conductivized area CDA1 and the other side of the channel area CA adjacent to the second conductivized area CDA2, respectively.

As previously described, each of the first conductivized area CDA1 and the second conductivized area CDA2 may be formed by conductivizing the area of the first active layer 420 excluding the channel area CA.

However, in a process of conductivizing the portion of the first active layer 420 into the conductive portion, a portion of the channel area CA overlapping with the first gate electrode 430 and adjacent to each of the first conductivized area CDA1 and the second conductivized area CDA2 may be partially subjected to the conductivizing process into the conductive portion.

Thus, the portion of the channel area CA overlapping with the first gate electrode 430 and adjacent to the first conductivized area CDA1 may be partially subjected to the conductivizing process into the conductive portion and thus may become the first boundary area ΔL1.

The first boundary area ΔL1 may be disposed in the first channel area CA1 of the first drain active layer 421.

Further, the portion of the channel area CA overlapping with the first gate electrode 430 and adjacent to the second conductivized area CDA2 may be partially subjected to the conductivizing process into the conductive portion and thus may become the second boundary area ΔL2.

The second boundary area ΔL2 may be disposed in the second channel area CA2 of the first source active layer 422.

Each of the first boundary area ΔL1 and the second boundary area ΔL2 may have a higher carrier concentration than that of the channel area CA.

The first boundary area ΔL1 and the second boundary area ΔL2 may have a Fermi level similar to those of the first conductivized area CDA1 and the second conductivized area CDA2, respectively.

In this way, the conductivity of the first boundary area ΔL1 and the second boundary area ΔL2 as both opposing edges of the channel area CA may increase in the process in which the portion of the first active layer 420 is converted into the first conductivized area CDA1 and the second conductivized area CDA2.

Lengths of the first boundary area ΔL and the second boundary area ΔL2 may be referred to as a first conductivization penetration length ΔL1 and a second conductivization penetration length ΔL2, respectively.

An area corresponding to a portion of the channel area CA excluding the first conductivization penetration length ΔL1 and the second conductivization penetration length ΔL2 in a total length of the channel area CA may be defined as an effective channel area.

The length of the first channel area CAL may exceed at least the first conductivization penetration length ΔL1.

Accordingly, in the first drain active layer 421, an area corresponding to a length excluding the first conductivization penetration length ΔL1 in a total length of the first channel area CA1 may become a first effective channel area. Thus, in the first drain active layer 421, the effective channel area with the low carrier mobility may be secured.

In this way, in the first drain active layer 421, the effective channel area with the low carrier concentration and thus the low carrier mobility may be secured. Thus, even when current flows from the first source electrode 442 to the first drain electrode 441, the possibility at which the hot carrier stress occurs may be greatly reduced.

According to an embodiment of the present disclosure as described as above, the carrier mobility of the first drain active layer 421 connected to the first drain electrode 441 is lower than that of the first source active layer 422 connected to the first source electrode 442. Thus, even when the first source active layer 422 is made of the high-carrier mobility material, the occurrence of the hot carrier stress in the first drain active layer 421 may be reduced.

That is, the first drain active layer 421 connected to the first drain electrode 441 may be formed to have the low carrier mobility, and the carrier concentration in the first channel area CA1 may be reduced. Even when current flows in the unidirectional direction from the first source electrode 442 to the first drain electrode 441, the occurrence of the hot carrier stress in the first drain active layer 421 near the first channel area CA1 may be reduced.

Further, according to an embodiment of the present disclosure, the first drain active layer 421 and the first source active layer 422 having different mobilities may be arranged side by side and may be disposed in the same layer, and each thereof may be formed as a single layer. Thus, deterioration of a step coverage of the gate insulating layer 160 formed on the first drain active layer 421 and the first source active layer 422 may be reduced.

As the degradation of the step coverage of the gate insulating layer 160 is reduced, the stabilization effect of device characteristics may be obtained.

Moreover, according to an embodiment of the present disclosure, the first active layer 420 of the first thin-film transistor T1 included in the gate driver 40 has relatively high carrier mobility. Thus, even when a length of the first active layer 420 is reduced, high current characteristics may be secured.

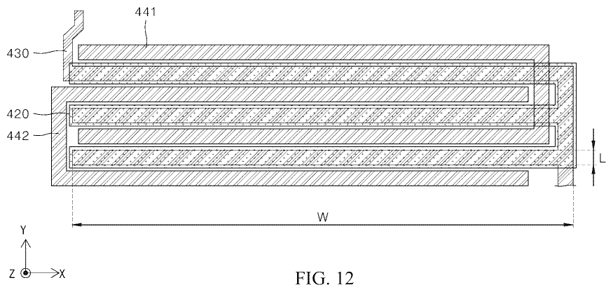

For example, referring further to FIG. 12, a width in a left and right direction in the X-axis direction of the gate driver 40 is affected by a width W in the left and right directions in the X-axis direction of the first active layer 420.

In addition, a length in the left and right direction in the Y-axis direction of the gate driver 40 is affected by a length L in the left and right direction in the Y-axis direction of the first active layer 420.

As previously described, the first active layer 420 of the first thin-film transistor T1 is formed to have relatively high carrier mobility. Thus, even when a total area occupied with the first active layer 420 is reduced by reducing the length L and the width W of the first active layer 420, high current characteristics sufficient for the operation of the display panel may be secured.

Accordingly, according to the embodiment of the present disclosure, while the high current characteristics of the first thin-film transistor T1 is maintained, a portion of the non-display area NA occupied with the gate driver 40 may be reduced by reducing the length L and the width W of the first active layer 420 of the first thin-film transistor T1, such that the display device 1 with a narrow bezel may be realized.

In this case, an effect of reducing the width W of the first active layer 420 may be greater than an effect of reducing the length L thereof. Thus, a bezel width in the left and right direction of the display device 1 may be effectively reduced.

A second active layer 320 may be disposed on the buffer layer 150 in an area where the second thin-film transistor T2 is disposed.

The second active layer 320 of the second thin-film transistor T2 and the first active layer 420 of the first thin-film transistor T1 may be disposed in the same plane.

The second active layer 320 may include an oxide semiconductor material.

The second active layer 320 may have a lower carrier mobility than that of the first active layer 420 and may include an oxide semiconductor material with a relatively low carrier mobility.

In one example, the second active layer 320 may include the same low carrier mobility oxide semiconductor material as that of the first drain active layer 421.

In one example, the second active layer 320 of the low carrier mobility may include at least one of an IGZO (InGaZnO)-based oxide semiconductor material [Ga concentration≥In concentration], a GZO (GaZnO)-based oxide semiconductor material, an IGO (InGaO)-based oxide semiconductor material, and a GZTO (GaZnSnO)-based oxide semiconductor material.

As the second active layer 320 of the second thin-film transistor T2 is formed to have relatively low carrier mobility, the high switching characteristics required for the switching thin-film transistor may be secured, such that the reliability of the switching characteristics of the second thin-film transistor T2 may be increased.

The gate insulating layer 160 may be formed on the second active layer 320, and a second upper gate electrode 330 may be formed on the gate insulating layer 160.

The third interlayer insulating layer 170 may be formed on the second upper gate electrode 330.

A second drain electrode 341 and a second source electrode 342 may be disposed on the third interlayer insulating layer 170.

The second drain electrode 341 may be connected to one side of the second active layer 320 via a second drain contact hole 341h extending through the third interlayer insulating layer 170 and the gate insulating layer 160.

Additionally, the second source electrode 342 may be connected to the other side of the second active layer 320 via a second source contact hole 342h extending through the third interlayer insulating layer 170 and the gate insulating layer 160.

In this case, since the second drain electrode 341 and the second source electrode 342 are formed in a symmetrical structure with each other, the second thin-film transistor T2 may operate in a bidirectional manner rather than in a unidirectional manner.

As the second thin-film transistor T2 operates in the bidirectional manner, the characteristics required for the switching thin-film transistor may be satisfied.

In addition, the second thin-film transistor T2 may have a double gate structure in which the second upper gate electrode 330 is disposed on top of the second active layer 320 and a second lower gate electrode 303 is disposed under the second active layer 320.

When the second thin-film transistor T2 has the double gate structure, a gate field applied to the channel area of the second active layer 320 may become stronger, such that a negative shift in the threshold voltage may occur.

In this case, as the second active layer 320 of the second thin-film transistor T2 is formed to have the low carrier mobility, the threshold voltage may shift in a positive shift direction.

Accordingly, in the second thin-film transistor T2, the threshold voltage thereof may be as close to 0 as much as possible due to a cancellation effect between the negative shift in the threshold voltage due to the double gate structure and the positive shift in the threshold voltage due to the material with the low carrier mobility.

In addition, since the second thin-film transistor T2 has the double gate structure, the S-factor value may be small, so that the second thin-film transistor T2 can be turned on even under a lower voltage. Thus, the switching characteristics of the second thin-film transistor T2 may be improved.

According to an embodiment of the present disclosure as described as above, the carrier mobilities of the active layers of the first thin-film transistor T1 and the second thin-film transistor T2 requiring different characteristics are set to be different from each other, thereby satisfy both the characteristics required for the plurality of thin-film transistors with the different functions.

Moreover, according to an embodiment of the present disclosure, in the first thin-film transistor T1 which requires the high current characteristics, the active layer thereof has the relatively high carrier mobility. In the second thin-film transistor T2 which requires the high switching characteristics, the active layer thereof has the relatively low carrier mobility. Thus, both the thin-film transistors respectively requiring the high current characteristics and the high switching characteristics may be realized.

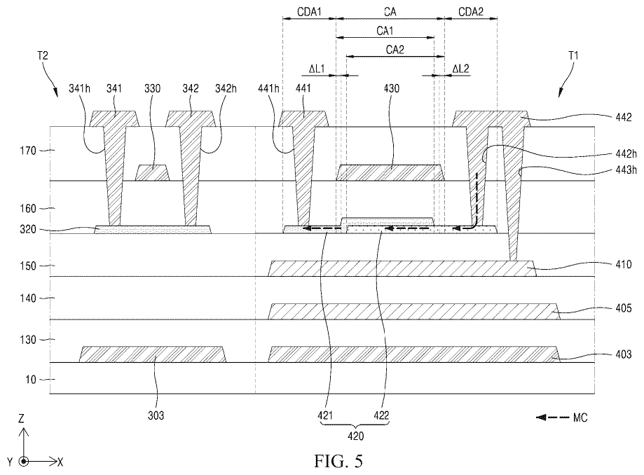

Hereinafter, FIG. 5 to FIG. 10 will be referred to respectively to describe thin-film transistor substrates according to some further embodiment of the present disclosure.

However, in second to seventh embodiments as described below, the descriptions of contents duplicate with those about the thin-film transistor substrate according to the first embodiment as described above with reference to FIG. 4 will be omitted. Rather, following descriptions focus on different configurations thereof therefrom.

Referring to FIG. 5, in the thin-film transistor substrate according to the second embodiment, the first drain active layer 421 may extend toward the first source electrode 442 so that the first drain active layer 421 covers a top surface of the first source active layer 422. Thus, the first drain active layer 421 includes a first portion that is on a same plane as the first source active layer 422 and a second portion that is over the first source active layer 422 such that the second portion of the first drain active layer 421 is between the first gate electrode 430 and the first source active layer 422.

Therefore, the first active layer 420 may be formed as a double layer stack composed of two layers, that, lower and upper level layers.

For example, the first drain active layer 421 and the first source active layer 422 may be disposed in a lower level layer of the stack. The first drain active layer 421 may extend from the first drain active layer 421 of the lower level layer and may be disposed in an upper level layer of the stack.

In this case, the first channel area CA1 of the first drain active layer 421 may become larger by a length by which the first drain active layer 421 extends from the first drain active layer 421 of the lower level layer so as to be disposed in the upper level layer of the stack.

As the first drain active layer 421 is disposed to cover the top surface of the first source active layer 422, the top surface of the first drain active layer 421 may be closer to the first gate electrode 430 than the top surface of the first source active layer 422.

As the first drain active layer 421 is located closer to the first gate electrode 430 than the first source active layer 422 is, a gate field may be strongly applied to the first drain active layer 421, so that the first channel area CA1 of the first drain active layer 421 may act as the main channel area.

In this way, when the first channel area CA1 of the low carrier mobility becomes the main channel area, it may be difficult to achieve the high current characteristic effect of the thin-film transistor.

Accordingly, according to an embodiment of the present disclosure, a difference between the carrier mobility of the first source active layer 422 and the carrier mobility of the first drain active layer 421 may be set to be larger.

In this case, the carrier mobility of the first source active layer 422 may be set to be higher by at least approximately 10 cm²/V·s than the carrier mobility of the first drain active layer 421. However, embodiments of the present disclosure are not limited thereto.

Accordingly, instead of the first channel area CA1 of the first drain active layer 421 closer to the first gate electrode 430 than the first source active layer 422, the second channel area CA2 of the first source active layer 422 relatively further away from the first gate electrode 430 may act as the main channel area.

Therefore, referring to FIG. 5, the main current MC flowing from the first source electrode 442 may flow through the second channel area CA2 and the first channel area CA1 in the lower level layer of the stack and then may flow to the first drain electrode 441.

In one example, the first channel area CA1 disposed in the upper level layer may function as a protective capping layer that protects the second channel area CA2 disposed in the lower level layer.

During a process of forming the thin-film transistor, the first active layer 420 constituting the channel area CA may be damaged during many processes for forming the thin-film transistor.

In this case, a portion of the first channel area CA1 of the first drain active layer 421 in the upper level layer which does not constitute the main channel area covers the upper of the second channel area CA2. Thus, the first channel area CA1 of the first drain active layer 421 of the upper level layer may function to prevent the damage to the second channel area CA2 of the lower level layer acting as the main channel area.

As the damage to the second channel area CA2 acting as the main channel area may be reduced, the reliability of the thin-film transistor may be improved.

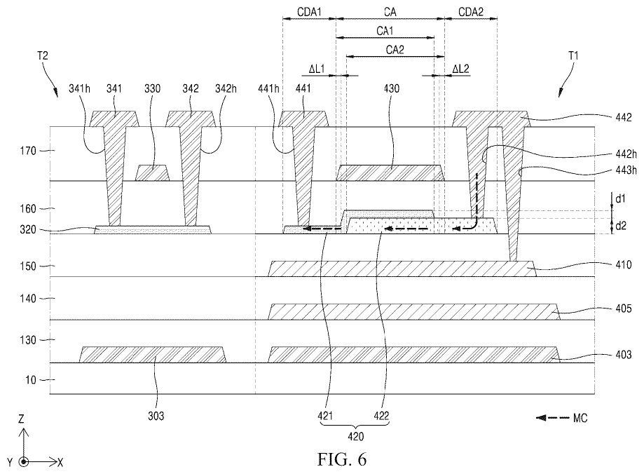

Further, referring to FIG. 6, in the thin-film transistor substrate according to the third embodiment of the present disclosure, a thickness d2 of the first source active layer 422 may be larger than a thickness d1 of the first drain active layer 421. That is the thickness d2 of the first source active layer 422 is thicker than the thickness d1 of the first portion of the first drain active layer 421 that is on the same plane as the first source active layer 422 and the thickness d1 of the second portion of the first drain active layer 421 that is over the first source active layer 422.

When the thickness d2 of the first source active layer 422 is larger than the thickness d1 of the first drain active layer 421, the second channel area CA2 of the first source active layer 422 disposed under the first channel area CA1 of the first drain active layer 421 may act as the main channel area even though the difference between the carrier mobility of the first source active layer 422 and the carrier mobility of the first drain active layer 421 is not set to be larger.

As the thickness of the second channel area CA2 of the first source active layer 422 increases, a stronger gate field may be applied to the second channel area CA2.

Accordingly, instead of the first channel area CA1 of the first drain active layer 421 that closer to the first gate electrode 430 than the first source active layer 422 acting as the main channel area, the second channel area CA2 of the first source active layer 422 that is relatively further away from the first gate electrode 430 may act as the main channel area.

Therefore, referring to FIG. 6, the main current MC flowing from the first source electrode 442 may flow through the second channel area CA2 of the lower level layer and the first channel area CA1 of the lower level layer and then may flow to the first drain electrode 441.

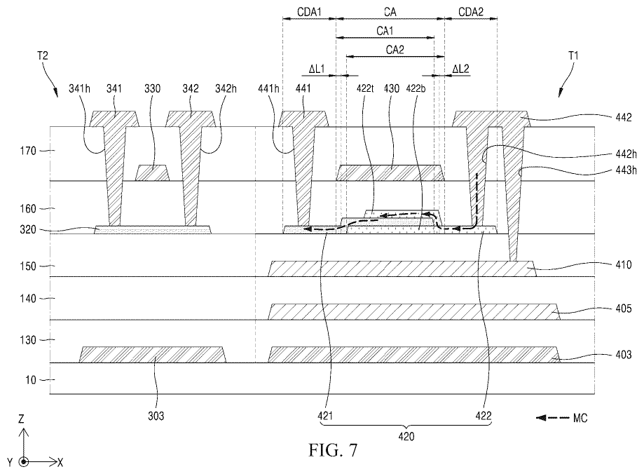

Referring to FIG. 7, the thin-film transistor substrate according to the fourth embodiment of the present disclosure may include a multi-layer active layer 420 composed of a stack of three layers.

The first source active layer 422 may include a first lower source active layer 422b disposed so that a partial area thereof is covered with the first drain active layer 421, and a first upper source active layer 422t extending from the first lower source active layer 422b so as to cover at least a partial area of the first drain active layer 421 that covers the first lower source active layer 422b. Thus, a portion of the first drain active layer 421 is between the first lower source active layer 422b and the first upper source active layer 422t.

For example, the first drain active layer 421 and the first source active layer 422 may be disposed in a lower level layer, the first drain active layer 421 may be disposed in a middle level layer, and the first source active layer 422 may be disposed in an upper level layer.

The first drain active layer 421 of the lower level layer and the first drain active layer 421 of the middle level layer may be connected to each other along a side surface of the first source active layer 422 of the lower level layer. The first source active layer 422 of the lower level layer and the first source active layer 422 of the upper level layer may be connected to each other along a side surface of the first drain active layer 421 of the middle level layer.

In this case, the first upper source active layer 422t and the first lower source active layer 422b may be formed to have the same carrier mobility. However, embodiments of the present disclosure are not limited thereto.

Additionally, the first upper source active layer 422t and the first lower source active layer 422b may be formed in different processes.

For example, after forming the first lower source active layer 422b and forming the first drain active layer 421, the first upper source active layer 422t may be additionally formed.

The first upper source active layer 422t may not cover a partial area of the first channel area CA1 of the first drain active layer 421, so that a partial area of the first channel area CA1 of the first drain active layer 421 may be directly exposed to the first gate electrode 430.

For example, the first upper source active layer 422t may extend as much as possible such that an end thereof may not invade the first boundary area ΔL1.

The first active layer 420 is constructed such that the first drain active layer 421 of the low carrier mobility is surrounded with the first source active layer 422 of the high carrier mobility in a sandwiched manner, and the first active layer 420 of the low carrier mobility spaces upper and lower portions of the first source active layer 422 of the high carrier mobility from each other.

That is, the first active layer 420 may be constructed such that the active layers having different carrier mobilities are alternately stacked on top of each other in the vertical direction.

Since the first upper source active layer 422t is located closest to the first gate electrode 430 and has the high carrier mobility, the first upper source active layer 422t may constitute the main channel area.

Therefore, referring to FIG. 7, the main current MC flowing from the first source electrode 442 may flow through the partial area of the second channel area CA2 of the first lower source active layer 422b of the lower level layer and then may flow through the second channel area CA2 of the first upper source active layer 422t of the upper level layer, and may flow through the first channel area CA1 of the first drain active layer 421 of the middle and lower level layers and then may flow to the first drain electrode 441.

The first lower source active layer 422b disposed in the lower level layer may function as a carrier support layer that supplements the carriers into the first upper source active layer 422t.

In order to increase the intensity of the current passing through the second channel area CA2 of the first upper source active layer 422t, the carrier mobility of the first upper source active layer 422t may be further increased or the thickness thereof may be increased.

However, when the carrier mobility of the first upper source active layer 422t is excessively increased, the influence of the main channel area adjacent to the first gate electrode 430 may become excessively large.

Accordingly, a threshold voltage of the thin-film transistor may change, and it may be difficult to control an interface between the first upper source active layer 422t constituting the main channel area and the gate insulating layer 160.

Therefore, instead of directly increasing the carrier mobility of the first upper source active layer 422t, a scheme of indirectly increasing the carrier mobility of the first upper source active layer 422t, for example, transferring the carrier of the first lower source active layer 422b to the first upper source active layer 422t may be applied to the thin-film transistor according to the present disclosure.

For example, the strong gate field acts in an area where the voltage applied to the first gate electrode 430 is high. Thus, the gate field is affected by the first lower source active layer 422b of the lower level layer. Thus, as the carriers in the first lower source active layer 422b migrate to the first upper source active layer 422t, the carriers may be supplemented to the first upper source active layer 422t.

As the carriers are supplemented to the first upper source active layer 422t, the carrier mobility of the first upper source active layer 422t indirectly increases. Thus, the intensity of the current passing through the second channel area CA2 of the first upper source active layer 422t may be increased while maintaining the stability of the threshold voltage of the thin-film transistor.

Accordingly, a portion of the first drain active layer 421 between the first upper source active layer 422t and the first lower source active layer 422b may act as an isolation layer that structurally isolates the first upper source active layer 422t and the first lower source active layer 422b from each other.

As the first drain active layer 421 structurally isolates the first upper source active layer 422t and the first lower source active layer 422b from each other, the thickness of the first upper source active layer 422t may be prevented from directly increasing significantly.

According to an embodiment of the present disclosure as described above, the first active layer 420 is embodied as the stack of the plurality of layers with different carrier mobility, thereby allowing the threshold voltage to be more easily controlled in the first active layer 420 based on high current characteristics.

Further, according to an embodiment of the present disclosure, a significant area of an effective channel area of the first active layer 420 constituting the main channel may be made of a relatively high carrier mobility material. Thus, high current may be allowed to flow through the thin-film transistor, such that a display device with high luminance may be realized.

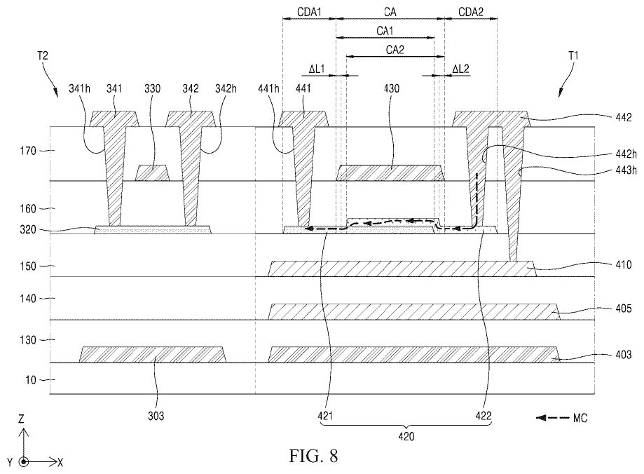

Referring to FIG. 8, in the thin-film transistor substrate according to the fifth embodiment, the first source active layer 422 extends toward the first drain electrode 441 so as to cover a top surface of the first drain active layer 421.

Therefore, the first active layer 420 may be formed as a double layer composed of two layers, that is, a lower level layer and an upper level layer.

For example, the first drain active layer 421 and the first source active layer 422 may be disposed in the lower level layer, and the first source active layer 422 may be disposed in the upper level layer.

In this case, a length of the first channel area CA1 of the first drain active layer 421 disposed in the lower level layer is larger than a length of the second channel area CA2 of the first source active layer 422 disposed in the lower level layer.

However, as the second channel area CA2 of the first source active layer 422 disposed in the upper level layer extends toward the first drain electrode 441, a total length of the first source active layer 422 may increase.

The first source active layer 422 extends so as not to cover a partial area of the first channel area CA1 of the first drain active layer 421. Thus, the partial area of the first channel area CA1 of the first drain active layer 421 may be directly exposed to the first gate electrode 430.

For example, the first source active layer 422 in the upper level layer may extend as much as possible such an end thereof does not invade the first boundary area ΔL1.

A top surface of the first source active layer 422 may be closer to the first gate electrode 430 than a top surface of the first drain active layer 421 may be.

As the first source active layer 422 of the high carrier mobility is located closer to the first gate electrode 430 than the first drain active layer 421 of the low carrier mobility is, a strong gate field is applied to the first source active layer 422. Thus, the second channel area CA2 of the first source active layer 422 of the upper level layer may act as the main channel area.

Therefore, referring to FIG. 8, the main current MC flowing from the first source electrode 442 may flow through the second channel area CA2 of the lower level layer and then the second channel area CA2 of the upper level layer and then may flow to the first drain electrode 441 through the first channel area CA1 of the lower level layer.

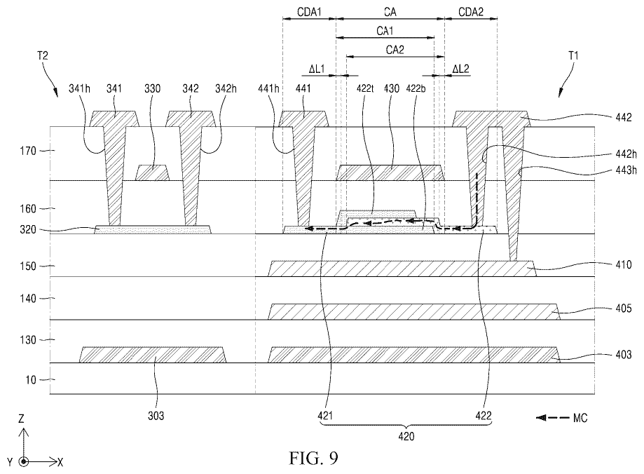

Referring to FIG. 9, the thin-film transistor substrate according to the sixth embodiment of the present disclosure may include a multi-layer active layer 420 composed of a stack of three layers, that is, upper, middle, and lower level layers.

The first drain active layer 421 is constructed to include a first lower drain active layer 421b having a partial area that is covered with the first source active layer 422, and a first upper drain active layer 421t extending from the first lower drain active layer 421b so as to cover at least a partial area of the first source active layer 422 covering the first lower drain active layer 421b.

As the first upper drain active layer 421t is disposed to cover a top surface of the first source active layer 422, a top surface of the first upper drain active layer 421t may be closer to the first gate electrode 430 than the top surface of the first source active layer 422 may be.

As the first upper drain active layer 421t is located closer to the first gate electrode 430 than the first source active layer 422 is, the strong gate field is applied to the first drain active layer 421. Thus, the first channel area CA1 of the first drain active layer 421 may act as the main channel area.

When the first channel area CA1 of the low carrier mobility acts as the main channel area, it may be difficult to achieve the high current characteristic effect of the thin-film transistor.

Accordingly, according to an embodiment of the present disclosure, the difference between the carrier mobility of the first source active layer 422 and the carrier mobility of the first drain active layer 421 may be set to be larger.

In this case, the carrier mobility of the first source active layer 422 may be set to be higher by approximately 10 cm²/V·s than the carrier mobility of the first drain active layer 421. However, embodiments of the present disclosure are not limited thereto.

Accordingly, instead of the first channel area CA1 of the first upper drain active layer 421t closer to the first gate electrode 430 than the first source active layer 422, the second channel area CA2 of the first source active layer 422 that is relatively further away from the first gate electrode 430 may act as the main channel area.

Therefore, referring to FIG. 9, the main current MC flowing from the first source electrode 442 may flow through the first source active layer 422 of the lower level layer and then the first channel area CA1 of the middle level layer and then the first drain active layer 421 of the lower level layer and then may flow to the first drain electrode 441.

The first channel area CA1 of the first upper drain active layer 421t disposed in the upper level layer and the first lower drain active layer 421b disposed in the lower level layer may function as a protective capping layer that protects the second channel area CA2 disposed in the middle level layer.

During the process of forming the thin-film transistor, the first active layer 420 constituting the channel area CA may be damaged during the process.

In this case, the first channel area CAL of the first upper drain active layer 421t disposed in the upper level layer which does not constitute the main channel area and the first channel area CA1 of the first lower drain active layer 421b disposed in the lower level layer which does not constitute the main channel area may cover the upper and lower surfaces of the second channel area CA2, respectively and thus may function to prevent the damage to the second channel area CA2 of the middle level layer constituting the main channel area.

As the damage to the second channel area CA2 constituting the main channel area is reduced, the reliability of the thin-film transistor may be improved.

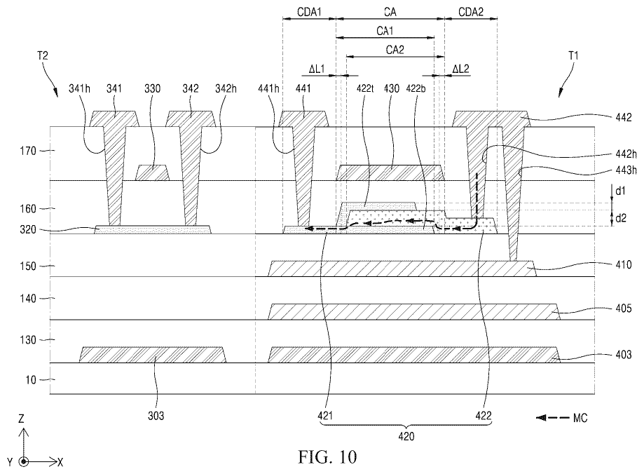

Further, referring to FIG. 10, the thin-film transistor substrate according to the seventh embodiment of the present disclosure has a stack structure according to FIG. 8, and further has a structure in which the thickness d2 of the first source active layer 422 is larger than the thickness d1 of the first upper drain active layer 421t.

Thus, when the thickness d2 of the first source active layer 422 is larger than the thickness d1 of the first upper drain active layer 421t, the second channel area CA2 of the first source active layer 422 may act as the main channel area even though the difference between the carrier mobility of the first source active layer 422 and the carrier mobility of the first upper drain active layer 421t is not set to be large.

As the thickness of the second channel area CA2 of the first source active layer 422 increases, a stronger gate field may be applied to the second channel area CA2. Thus, instead of the first channel area CAL of the first upper drain active layer 421t closer to the first gate electrode 430, the second channel area CA2 of the first source active layer 422 relatively further away from the first gate electrode 430 may act as the main channel area.

Therefore, referring to FIG. 10, the main current MC flowing from the first source electrode 442 may flow through the second channel area CA2 of the upper level layer and the first channel area CA1 of the lower level layer, and then may flow to the first drain electrode 441.

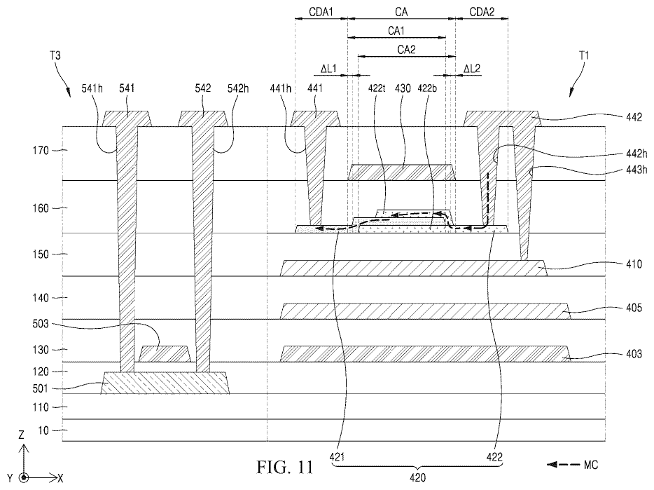

Referring to FIG. 11, FIG. 11 shows a cross-sectional view of the first thin-film transistor T1 and the third thin-film transistor T3 disposed in the gate driver 40.

Since the first thin-film transistor T1 disposed on the substrate 10 is substantially the same as that in the previously described embodiments, detailed description thereof will be omitted.

The buffer layer 110 may be formed on the substrate 10, and a third active layer 501 may be formed on the buffer layer 110.

As previously described, the first active layer 420 of the first thin-film transistor T1 may be formed to include an oxide semiconductor material.

On the contrary, the third active layer 501 of the third thin-film transistor T3 may include LTPS (Low Temperature Poly Silicon).

According to the present disclosure, the third thin-film transistor T3 may be embodied as the LTPS thin-film transistor and the first thin-film transistor T1 may be embodied as the LTPO (Low Temperature Polycrystalline Oxide) thin-film transistor.

The gate insulating layer 120 may be formed on the third active layer 501, and a third gate electrode 503 may be formed on the gate insulating layer 120.

The third gate electrode 503 may be formed in the same layer as a layer of the first capacitor electrode 403 disposed under the first thin-film transistor T1.

On the third gate electrode 503, the first interlayer insulating layer 130, the second interlayer insulating layer 140, the buffer layer 150, the gate insulating layer 160, and the third interlayer insulating layer 170 may be sequentially stacked.

A third drain electrode 541 and a third source electrode 542 may be formed on the third interlayer insulating layer 170, and may be connected to the third active layer 501 via a third drain contact hole 541h and a third source contact hole 542h, respectively.

Due to the presence of the third thin-film transistor T3 embodied as the LTPS thin-film transistor, a sufficient space in which a capacitor CQ to secure additional capacitor capacity is disposed may be secured under the first thin-film transistor T1 as the oxide thin-film transistor.

Accordingly, according to the present disclosure, the capacitor CQ composed of a first capacitor electrode 403 and a second capacitor electrode 405 may be additionally formed in an area under the first thin-film transistor T1 and overlapping the first thin-film transistor T1 in the vertical direction. Thus, additional capacitor capacity may be secured, such that compensation ability can be improved.

A thin-film transistor substrate and a display device according to various aspects and embodiment of the present disclosure may be described as follows.

One aspect of the present disclosure provides a thin-film transistor substrate comprising: a substrate including a display area and a non-display area; a first thin-film transistor disposed on the non-display area of the substrate and including a first active layer, wherein one side portion and the other side portion of the first active layer have different carrier mobilities; and a second thin-film transistor disposed on the display area of the substrate and including a second active layer having a lower carrier mobility than a carrier mobility of the first active layer.

In accordance with some embodiments of the thin-film transistor substrate, the first thin-film transistor includes a first drain electrode and a first source electrode, wherein the first active layer includes a first drain active layer connected to the first drain electrode and a first source active layer connected to the first source electrode.

In accordance with some embodiments of the thin-film transistor substrate, the first drain active layer and the first source active layer are disposed in the same plane.

In accordance with some embodiments of the thin-film transistor substrate, the first drain active layer has a first carrier mobility, wherein the first source active layer has a second carrier mobility, wherein the first carrier mobility is lower than the second carrier mobility.

In accordance with some embodiments of the thin-film transistor substrate, the second active layer has the first carrier mobility.

In accordance with some embodiments of the thin-film transistor substrate, the first active layer is composed of a stack of multiple active layers, wherein the second active layer is composed of a single active layer.

In accordance with some embodiments of the thin-film transistor substrate, the second thin-film transistor has a double gate structure including a second upper gate electrode located on top of the second active layer and a second lower gate electrode located under the second active layer.

In accordance with some embodiments of the thin-film transistor substrate, the thin-film transistor substrate further comprises: a first light blocking layer disposed under the first active layer; and a capacitor disposed under the first light blocking layer and including a first capacitor electrode and a second capacitor electrode, wherein the second capacitor electrode and the second lower gate electrode is disposed in the same plane.

In accordance with some embodiments of the thin-film transistor substrate, the capacitor is positioned to overlap the first thin-film transistor in a vertical direction.

In accordance with some embodiments of the thin-film transistor substrate, the thin-film transistor substrate further comprises a gate driver disposed on the non-display area of the substrate, wherein the first thin-film transistor acts as a GIP (gate-in-panel) type driving thin-film transistor included in the gate driver, wherein the second thin-film transistor acts as a switching thin-film transistor.

In accordance with some embodiments of the thin-film transistor substrate, each of the first active layer and the second active layer include an oxide semiconductor material.

In accordance with some embodiments of the thin-film transistor substrate, the thin-film transistor substrate further comprises a third thin-film transistor included in the gate driver and including a third active layer, wherein the third active layer includes low-temperature polycrystalline silicon.

Another aspect of the present disclosure provides a display device comprising: a substrate including a display area and a non-display area; a light-emitting element disposed on the display area of the substrate; and a gate driver disposed on the non-display area of the substrate and configured to provide a gate voltage to the display area, wherein the gate driver includes a first thin-film transistor, wherein the first thin-film transistor includes a first active layer, a first drain electrode, a first source electrode, and a first gate electrode, wherein the first active layer includes a first drain active layer connected to the first drain electrode and a first source active layer connected to the first source electrode, wherein a carrier mobility of the first drain active layer is lower than a carrier mobility of the first source active layer.

In accordance with some embodiments of the display device, the first active layer includes an oxide semiconductor material.

In accordance with some embodiments of the display device, a first light blocking layer is disposed under the first active layer, wherein the first light blocking layer is electrically connected to the first source electrode.

In accordance with some embodiments of the display device, the first active layer is composed of a single active layer.

In accordance with some embodiments of the display device, the first active layer is composed of a stack of multiple active layers.

In accordance with some embodiments of the display device, the first active layer is constructed such that the multiple active layers having different carrier mobilities are alternately stacked on top of each other in at least a portion of an area overlapping with the gate electrode.

In accordance with some embodiments of the display device, the first thin-film transistor is configured to allow current to flow therethrough in a unidirectional manner.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical concept or essential characteristics of the present disclosure. Therefore, it should be appreciated that the embodiments as described above is not restrictive but illustrative in all respects.

What is claimed is:

1. A thin-film transistor substrate comprising:
a substrate including a display area and a non-display area;
a first thin-film transistor on the non-display area of the substrate, the first thin-film transistor including a first active layer having a first side portion and a second side portion that is opposite the first side portion and has a second carrier mobility that is different from a first carrier mobility of the first side portion; and
a second thin-film transistor on the display area of the substrate, the second thin-film transistor including a second active layer having a carrier mobility that is less than the first carrier mobility of the first side portion and the second carrier mobility of the second side portion of the first active layer.

2. The thin-film transistor substrate of claim 1, wherein the first thin-film transistor includes a first drain electrode and a first source electrode,
wherein the first active layer includes a first drain active layer that corresponds to the first side portion and is connected to the first drain electrode and a first source active layer corresponds to the second side portion and is connected to the first source electrode.

3. The thin-film transistor substrate of claim 2, wherein the first drain active layer and the first source active layer are in a same plane.

4. The thin-film transistor substrate of claim 2, wherein the first drain active layer has the first carrier mobility and the first source active layer has the second carrier mobility that is greater than the first carrier mobility.

5. The thin-film transistor substrate of claim 4, wherein the second active layer has the first carrier mobility.

6. The thin-film transistor substrate of claim 1, wherein the first active layer comprises a stack of multiple active layers and the second active layer comprises a single active layer.

7. The thin-film transistor substrate of claim 1, wherein the second thin-film transistor comprises a second upper gate electrode that is over the second active layer and a second lower gate electrode that is under the second active layer.

8. The thin-film transistor substrate of claim 7, wherein the thin-film transistor substrate further comprises:
a first light blocking layer under the first active layer; and
a capacitor under the first light blocking layer, the capacitor including a first capacitor electrode and a second capacitor electrode,
wherein the second capacitor electrode and the second lower gate electrode are in a same plane.

9. The thin-film transistor substrate of claim 8, wherein the capacitor overlaps the first thin-film transistor in a vertical direction with respect to the substrate.

10. The thin-film transistor substrate of claim 1, wherein the thin-film transistor substrate further comprises:
a gate driver on the non-display area of the substrate,
wherein the first thin-film transistor is included in the gate driver and the second thin-film transistor is in the display area.

11. The thin-film transistor substrate of claim 10, wherein each of the first active layer and the second active layer include an oxide semiconductor material.

12. The thin-film transistor substrate of claim 11, wherein the thin-film transistor substrate further comprises:
a third thin-film transistor included in the gate driver and including a third active layer, the third active layer includes low-temperature polycrystalline silicon.

13. A display device comprising:
a substrate including a display area and a non-display area;
a light-emitting element on the display area of the substrate, the light-emitting element configured to emit light; and
a gate driver on the non-display area of the substrate and configured to provide a gate voltage to the display area, the gate driver including a first thin-film transistor on the non-display area that comprises a first active layer, a first drain electrode, a first source electrode, and a first gate electrode,
wherein the first active layer includes a first drain active layer connected to the first drain electrode and having a first carrier mobility and a first source active layer connected to the first source electrode and including a second carrier mobility that is greater than the first carrier mobility of the first drain electrode.

14. The display device of claim 13, wherein the first active layer includes an oxide semiconductor material.

15. The display device of claim 13, wherein a first light blocking layer is under the first active layer, the first light blocking layer electrically connected to the first source electrode.

16. The display device of claim 13, wherein the first active layer comprises a single active layer.

17. The display device of claim 13, wherein the first active layer comprises a stack of multiple active layers.

18. The display device of claim 17, wherein the stack of multiple active layers have different carrier mobilities are alternately stacked on top of each other in at least a portion of an area that overlaps with the first gate electrode.

19. The display device of claim 13, wherein current flows through the first thin-film transistor in a unidirectional manner.

20. A thin-film transistor comprising:
an oxide semiconductor layer comprising a drain active layer having a first carrier mobility and a source active layer having a second carrier mobility that is greater than the first carrier mobility;
a gate electrode overlapping a portion of oxide semiconductor layer and is spaced apart from the portion of the oxide semiconductor layer;
a drain electrode that is connected to the drain active layer; and
a source electrode that is connected to the source active layer.

21. The thin-film transistor of claim 20, wherein the drain active layer and the source active layer are on a same plane and a length of the drain active layer is less than a length of the source active layer.

22. The thin-film transistor of claim 20, wherein the drain active layer includes a first portion that is on a same plane as the source active layer and a second portion that is over the source active layer such that the second portion of the drain active layer is between the gate electrode and the source active layer.

23. The thin-film transistor of claim 22, wherein a thickness of the source active layer is thicker than a thickness of the first portion of the drain active layer and a thickness of the second portion of the drain active layer.

24. The thin-film transistor of claim 22, wherein the source active layer includes a portion that overlaps the second portion of the drain active layer such that the second portion of the drain active layer is between the portion of the source active layer and the source active layer that is on the same plane as the first portion of the drain active layer.

25. The thin-film transistor of claim 20, wherein the source active layer includes a first portion that is on a same plane as the drain active layer and a second portion that is over the drain active layer such that the second portion of the source active layer is between the gate electrode and the drain active layer.

26. The thin-film transistor of claim 25, wherein the drain active layer includes a portion that overlaps the second portion of the source active layer such that the second portion of the source active layer is between the portion of the drain active layer and the drain active layer that is on the same plane as the first portion of the source active layer.

27. The thin-film transistor of claim 26, wherein a thickness of the first portion of the source active layer and a thickness of the second portion of the source active layer are thicker than a thickness of the drain active layer.

28. The thin-film transistor of claim 26, wherein the thin-film transistor is included in a gate driver.
